(19) United States
(12) Patent Application Publication
(10) Pub. No.: US 2024/0100563 A1
(43) Pub. Date: Mar. 28, 2024

(54) ENHANCED COPOLYMER SYNTHESIS METHODS AND APPLICATIONS THEREOF

(71) Applicant: THE CURATORS OF THE UNIVERSITY OF MISSOURI, COLUMBIA, MO (US)

(72) Inventors: Quinton K. Wyatt, Columbia, MO (US); Matthias J. Young, Columbia, MO (US); Patrick J. Kinlen, Fenton, MO (US); Nikhila C. Paranamana, Columbia, MO (US)

(21) Appl. No.: 18/530,742

(22) Filed: Dec. 6, 2023

Related U.S. Application Data
(63) Continuation-in-part of application No. 17/070,284, filed on Oct. 14, 2020.

(51) Int. Cl. B05D 1/36; B05D 1/00

(52) U.S. Cl. CPC B05D 1/36; B05D 1/60; B05D 2504/00; B05D 2518/00

(57) ABSTRACT

Unique polymers and copolymers generated via oMLD processes are described alongside the methods for tuning such polymer and copolymer structures and redox chemistries. The polymers and copolymers described can incorporate monomeric species previously held to have too high an oxidation potential for successful use in oMLD, can exhibit unexpected redox chemistry from the adjustable incorporation of primary amine monomers and resulting azo functional groups, and show superior performance metrics when compared to polymers and copolymers synthesized by other methods. Applications for these polymers and copolymers are also described.

### CROSS-REFERENCE TO RELATED APPLICATIONS

This application is a Continuation-in-part Application of U.S. application Ser. No. 17/070,284 filed Oct. 14, 2020, the content of which (text, drawings, and claims) is incorporated herein by reference. This application also claims priority to U.S. Provisional Application No. 63/415,053, filed Oct. 11, 2022, the content of which (text, drawings, and claims) is incorporated herein by reference.

### GOVERNMENT RIGHTS

This invention was made with government support under 2131282 awarded by the National Science Foundation. The government has certain rights in the invention.

### TECHNICAL FIELD

The present teachings relate to electrically conductive and redox active polymers, and particularly to controlled formation of polymer and copolymer layers for applications in devices such as battery electrodes, sensors, and desalination devices.

### BACKGROUND

Conjugated, conductive and/or ion-capturing polymers are increasingly of interest for energy conversion and storage, desalination, chemical sensing, textiles, and other technologies. Such polymers can be made without the use of metals which, in most electrochemical applications, are often rare, expensive, and/or environmentally troublesome. Additionally, such polymers can boast high theoretical capacity and conductivity values, and are theoretically amenable to integration into a wide variety of device designs.

Historically, however, polymers have achieved experimental capacities and conductivities that fall far short of the promise of their theoretical values. In part, this failure is thought to stem from traditional methods for synthesizing these polymers and applying them to substrates. The ideal synthesis for such polymers would enable layer-by-layer control of a conjugated polymer's formation, so that polymer thickness and local molecular structure could be finely tuned to a given end use. Many applications, such as in energy storage, stand to benefit from thin conjugated polymer films with uniform and consistent local molecular structures. However, the relatively less controlled synthetic methods that see significant use in the field, such as solution-phase chemical polymerization, frequently result in the formation of undesirably thick polymers with nonideal local molecular structures such as rough agglomerations and fibers. Subsequent processing of these nonideal structures into applied polymer films generally permits only poor control over the roughness, thickness, and local structure of the resulting polymer film. Additionally, the diffusion of ions through such polymers is inhibited by the polymers' increased thickness, leading to higher overpotentials and lower capacities. Other polymer synthesis and application techniques, such as electrodeposition, can offer some finer control over polymer thickness, but can also result in nonideal local structures and electrically resistive phases. Furthermore, electrodeposition often fails when used to apply a polymer film to a porous or nonconductive substrate.

Oxidative molecular layer deposition (oMLD) is a promising approach to polymer synthesis and deposition that stands to resolve these problems and provide uniform thin film polymers. oMLD relies on alternating, sequential applications of gas phase chemical precursors. In most cases, these precursors comprise a monomer and an oxidant. By alternately dosing a substrate with fixed quantities of monomer and oxidant, one can cause these precursors to undergo self-limiting reactions, generating thin film polymers on a layer-by-layer basis. Additionally, oMLD frequently obviates the use of additives such as side chains that are practically required in solution-based polymer processing, resulting in a more chemically pure product. Hence, it is the properties of the polymer's more pure and controlled local structures, rather than those of its defects or undesired molecular structures, that come to dominate the macroscopic properties of the polymer product.

However, oMLD for conjugated polymer synthesis and deposition has so far only been demonstrated with a handful of monomers and oxidants. Furthermore, some candidate monomers have failed to generate the desired polymer films via oMLD due to previously unknown mechanistic restrictions. As a result, the oMLD polymerization methods described in prior work have failed to consistently and straightforwardly enable the use of primary amine monomers or monomers whose oxidation potentials are too great in magnitude to react with oxidants such as MoCl₅.

Furthermore, the unique and previously relatively unexplored mechanisms of oMLD polymerization can result in unique polymer chemistries, such as the formation of unexpected functional groups. Since prior oMLD polymerization methods did not consider these unique polymer product chemistries, they could not enable the modulation of polymer products to either emphasize or deemphasize particular functional groups.

Thus, there is a need for enhanced methods of oMLD polymerization that enable both the use of monomer species with primary amines and/or high oxidation potentials, as well the ability to modulate polymer products that incorporate such monomer species.

### BRIEF SUMMARY

In various embodiments, the present description provides enhanced oMLD methods for controlled synthesis of polymers.

The described oMLD methods of polymer synthesis enable, in various embodiments, the use of monomeric species that do not otherwise undergo polymerization via oMLD due to their high oxidation potentials. In various embodiments, the present description enables one to predict which oxidant species will work for oMLD polymer synthesis.

In various embodiments, the described oMLD methods of polymer synthesis also enable the consistent incorporation of primary amine monomers into a copolymer product. The described methods enable one to predict which monomeric species comprising primary amine functional groups will successfully polymerize and which will not. Furthermore, the described methods enable the synthesis via oMLD of copolymers that comprise azo functional groups, and to control such syntheses to increase or decrease the relative population of azo functional groups in the desired copolymer.

In various embodiments, the present description also includes battery devices and methods for manufacturing the same.

### BRIEF DESCRIPTION OF THE FIGURES

FIG. 1A exemplarily illustrates a schematic of oMLD polymer or copolymer synthesis and deposition proceeding via sequential doses of at least one species of monomer and at least one species of chemical oxidant. Modifications described herein enable new polymer formulations, in accordance with various embodiments of the present disclosure.

FIG. 1B exemplarily illustrates an abstracted cyclic schematic of the process of FIG. 1A, emphasizing the sub-cycles within the larger cyclic process in accordance with various embodiments of the present disclosure.

FIG. 2 exemplarily illustrates a series of monomers containing sulfur, nitrogen, and/or oxygen atoms, as well as the theoretical polymers formed from each monomer via prior known non-oMLD polymerization methods. Prior known oMLD methods do not enable polymerization of the shown monomers, but the improved methods described herein do, in accordance with various embodiments of the present disclosure.

FIG. 3 shows exemplary data for the oMLD steady-state mass gain per cycle (MGPC) of several monomers grown with a MoCl₅ oxidant utilizing the enhanced methods described herein.

FIG. 4 shows two exemplary primary amine monomers and two respective exemplary products of the oMLD polymerization, each exhibiting unexpected azo group functionality in accordance with various embodiments of the present disclosure.

FIG. 5 exemplarily illustrates a schematic of a battery incorporating materials produced via enhanced oMLD methods in accordance with various embodiments of the present disclosure.

FIG. 6 provides x-ray photoelectron spectroscopy (XPS) data demonstrating that the attempted growth of Thi:Py and Fu:Py copolymers successfully integrated thiophene and furan monomers into their respective polymer products using the disclosed enhanced oMLD methods, in accordance with various embodiments of the present disclosure.

FIG. 7A shows exemplary Raman spectroscopy data comparing films generated by oMLD to demonstrate the unexpected formation of azo groups from primary amine monomers.

FIG. 7B shows exemplary cyclic voltammetry data comparing bare substrate, polypyrrole and polyaniline films generated by oMLD, demonstrating the previously unknown redox behavior of different primary amine oMLD polymers.

FIG. 7C provides exemplary comparative cyclic voltammetry data demonstrating the properties of copolymers produced by varying the ratio of Py and PDA monomer dosing cycles during oMLD synthesis using the enhanced methods disclosed herein, in accordance with various embodiments of the present disclosure.

FIG. 7D exemplarily illustrates copolymer structures formed by different cycle ratios of Py:PDA, in accordance with various embodiments of the present disclosure.

FIG. 8A provides two superimposed exemplary cyclic voltammograms and is provided to compare the electrochemical properties of polypyrrole films formed by oMLD methods in accordance with various embodiments of the present disclosure with those formed by electrodeposition.

FIG. 8B shows capacity values as a function of voltage sweep rate, drawn from voltametric measurements, for an exemplary series of polypyrrole films formed by oMLD methods in accordance with various embodiments of the present disclosure.

### DETAILED DESCRIPTION

The following detailed description illustrates the claimed invention by way of example and not by way of limitation. This description will clearly enable one skilled in the art to make and use the claimed invention, and describes several embodiments, adaptations, variations, alternatives and uses of the claimed invention, including what is believed to be the best mode of carrying out the claimed invention. Additionally, it is to be understood that the claimed invention is not limited in its applications to the details of construction and the arrangements of components set forth in the following description or illustrated in the drawings. The claimed invention is capable of other embodiments and of being practiced or being carried out in various ways. Also, it is to be understood that the phraseology and terminology used herein is for the purpose of description and should not be regarded as limiting.

The term “polymer” as used herein is considered to be inclusive of polymers made from a single repeating monomeric subunit as well as what are commonly called “copolymers,” or polymers made from more than one monomeric subunit. The term “copolymer” is used herein specifically to denote polymers made from more than one repeating monomeric subunit.

The following detailed description comprises both detailed descriptions of novel, unexpected polymers synthesized and applied by enhanced oMLD methods as well as techniques for tuning the functional composition of copolymers made by oMLD. An exemplary application of such polymers is also described.

Processes of oxidative molecular layer deposition (oMLD) for the formation of conformal thin film polymers has been described, as for example in Wyatt et. al, (Wyatt, Q. K.; Vaninger, M.; Paranamana, N. C.; Heitmann, T. W.; Kaiser, H.; Young, M. J. Oxidative Molecular Layer Deposition of Amine-Containing Conjugated Polymer Thin Films. ACS Appl. Polym. Mater. 2022, 4, 6156), the content of which is incorporated herein by reference in its entirety. As is discussed below, known oMLD processes have not enabled the synthesis of particular polymers described herein. Thus, in accordance with various embodiments of the present disclosure a description of enhanced oMLD processes is provided below which, among other considerations, takes care to distinguish at least one ‘first’ from at least one ‘second’ monomer species. Following thereafter are further details of the enhanced oMLD processes that specifically enable the use of high-oxidation-potential monomers and primary amine monomers. The description will then detail methods of more finely controlling the enhanced synthesis and composition of these polymers beyond what is known. With this established, the advantages of the methods and exemplary applications also described herein will be more readily apparent.

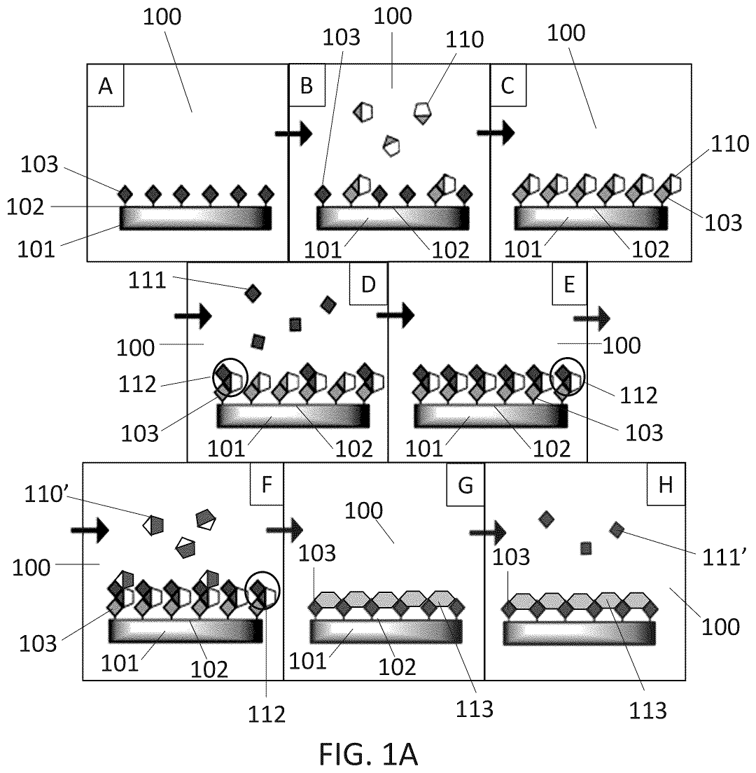

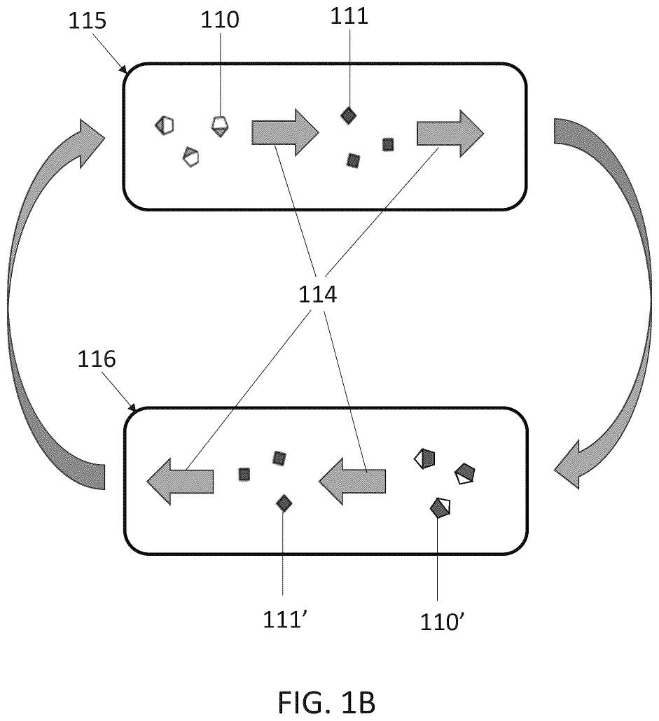

FIG. 1A provides a highly generalized exemplary scheme for enhanced oMLD polymer synthesis and deposition according to various exemplary embodiments of the present disclosure. oMLD synthesis presumes a reaction chamber 100 comprising a substrate 101 with a substrate surface 102, as seen in box A of FIG. 1A. In various exemplary embodiments, an optional surface layer 103 can be applied atop the substrate surface 102 before oMLD polymer synthesis and deposition proceeds, but this is not necessary.

To proceed with enhanced oMLD polymer synthesis and deposition, in various embodiments, at least one first gas phase monomer 110 is introduced into the reaction chamber 100 in a fixed quantity, in a process sometimes called ‘dosing,’ as shown in box B of FIG. 1A. The quantity of the at least one gas phase monomer 110 that is introduced can be controlled, for example, by flowing a fixed concentration of the at least one gas phase monomer 110 at a predefined flow rate for a predefined length of time. As seen in box B of FIG. 1A, a quantity of the at least one gas phase monomer 110 conformally binds to the substrate surface 102, the optional surface layer 103, or both.

Following this step and as seen in box C of FIG. 1A, the reaction chamber 100 is purged by application of vacuum and/or any other means known to one of ordinary skill in the art, leaving only the quantity of the at least one gas phase monomer 110 that is bound to the substrate surface 102, the optional surface layer 103, or both.

Once the reaction chamber 100 is purged, at least one first gas phase oxidant 111 is introduced to the reaction chamber 100 in a fixed quantity, as seen in box D of FIG. 1A. The fixed quantity of the at least one gas phase oxidant 111 can be controlled in a manner similar to that of the at least one gas phase monomer 110. Also as seen in box D of FIG. 1A, the quantity of the at least one gas phase oxidant 111 binds to the remaining quantity of the at least one gas phase monomer 110. In so doing, the at least one gas phase monomer 110 and at least one gas phase oxidant 111 become a surface-bound adduct 112. Each moiety of the surface-bound adduct 112 naturally comprises one moiety of the at least one gas phase monomer 110 and one moiety of the at least one gas phase oxidant 111.

Subsequently and as seen in box E of FIG. 1A, once the fixed quantity of the at least one gas phase oxidant 111 has been introduced to the reaction chamber 100, the reaction chamber is again purged, leaving the surface bound adduct 112 bound to the substrate surface 102, the optional surface layer 103, or both.

Proceeding next to box F of FIG. 1A, at least one second gas phase monomer 110′ is introduced to the reaction chamber 100. The at least one second gas phase monomer 110′ can undergo oxidation by the surface-bound adduct 112. The result of this oxidation is a desired copolymer 113, as seen in box G of FIG. 1A. Finally, the reaction chamber 100 is purged, leaving only the desired copolymer 113, as also seen in box G of FIG. 1A. Thus, a single layer of the desired copolymer 113 is formed. As further description to follow will make clear, maintaining clear distinctions between the steps depicted in FIG. 1A boxes A-H and their sequence is the first step in enabling the enhanced oMLD copolymer syntheses of the present disclosure.

As the above described process is a cyclical process, it can either end with the desired copolymer 113 or proceed further. If further growth is desired, the process can proceed to the step described with respect to box H of FIG. 1A, wherein at least one gas phase oxidant 111′ is introduced to the reaction chamber. The at least one second gas phase oxidant 111′ can be the same or different oxidant species as the at least one first gas phase oxidant 111. The reaction chamber is subsequently purged, and the process returns to the step depicted in box A of FIG. 1A, wherein the optional surface layer 103 is now known to comprise a quantity of the desired copolymer 113 and the at least one second gas phase oxidant 111′.

The foregoing exemplary description of the oMLD process comprises many possible variations. The substrate 101 can comprise a very wide array of materials. Candidate materials for the substrate 101 comprise, but are not limited to, conductive materials, nonconductive materials, semiconductors, metals, alloys, nonmetals, ceramics, foams, polymers, and any combination thereof. The substrate surface 102 can comprise materials other than those of the substrate 101. For example, in various embodiments the substrate surface 102 can comprise an oxide material that is not present in the bulk of the substrate 101.

The optional surface layer 103 can, in various exemplary embodiments, comprise a passivation layer and/or a previously applied layer of the desired polymer 113 or the desired copolymer 113. In various exemplary embodiments, the optional surface layer 103 can comprise a variety of materials, including but not limited to other conformal polymers, composites, inks, graphite, and metal oxides. As indicated, the optional surface layer 103 is not necessary, and the oMLD process can begin by introducing the at least one gas phase monomer 110 to a reaction chamber in which the substrate surface 102 is exposed.

The at least one first gas phase monomer 110 and/or the at least one second gas phase monomer 110′ can, without limitation and in various exemplary embodiments, include a quantity of one species of monomer, a quantity of two species of monomer present in a molar ratio relative to one another, or a quantity of more than two species of monomer present in a molar ratio relative to one another. Thus, it is within the scope of the present description to envision that the desired copolymer 113 can comprise a copolymer synthesized from two or more monomeric species. In various exemplary embodiments and without limitation, the desired copolymer 113 formed according to the present description from the at least one first gas phase monomer 110 and the at least one second gas phase monomer 110′ can comprise linear copolymers, such as block, alternating, periodic, statistical, stereoblock and gradient copolymers, as well as branched copolymers, such as graft and star copolymers, and any other copolymer known to one of ordinary skill in the art.

Suitable candidates for the at least one first gas phase monomer 110 and/or at least one second gas phase monomer 110′ include but are not limited to pyrrole, aniline, para-phenylenediamine, thiophene, ethylenedioxythiophene, quinone, hydroquinone, dimercaptothiadiazole, furan, phenol, pyrocatechol, resorcinol, and other cyclic or acyclic conjugated monomers with or without N and/or S heteroatoms, any of the foregoing with or without substituents, and combinations thereof. Suitable substituents can include, but are not necessarily limited to, one or more —R groups from the classes: alkyl (methyl, ethyl, propyl, butyl, isobutyl, etc.), alkenyl, phenyl, hydroxyl, carbonyl, aldehyde, carbonate ester, carboxylate, carboxyl, carboalkoxy, methoxy, ether, hemiacetal, hemiketal, acetal, ketal, carboxamide, amine, imine, imide, azo, nitrile, pyridyl, carbamate, sulfhydryl, or sulfide functionality. These —R group substituents can be located on the heteroatom or on any other atom in the molecule. Exemplary substitutions include N-methyl aniline, N,N-dimethylaniline, 1-methyl aniline, 2-methyl aniline, 3-methyl aniline, 1,2-dimethylaniline, 1,3-dimethylaniline, N,1,2-trimethylaniline, N,1,3-trimethylaniline, N,1,2,3-tetramethylaniline, N-methyl pyrrole, and 1-methyl pyrrole.

The desired copolymer 113 can, in various exemplary embodiments, acquire a charge capacity via the binding of ions. For example, the desired copolymer 113 can comprise functional groups that attract ions through electrostatic interactions or specific coordination. In various exemplary embodiments, the desired copolymer 113 can exhibit a charge capacity of at least 50% of its theoretical charge capacity, e.g., at least 51%, at least 52%, at least 53%, at least 54%, at least 55%, at least 56%, at least 57%, at least 58%, at least 59%, at least 60%, at least 61%, at least 62%, at least 63%, at least 64%, at least 65%, at least 66%, at least 67%, or at least 68% of their theoretical charge capacity. In various exemplary embodiments, the desired copolymer can exhibit a charge storage capacity of 90% of the theoretical charge storage capacity.

Various known methods for generating conjugated heteroatomic polymers require the use of plasticizers, sidechains, and/or other free organic molecule additives, but oMLD does not. Thus, the desired copolymer 113 can, in various exemplary embodiments, be exclusive of plasticizers, sidechains, or other free organic molecule additives. The oMLD process also, by virtue of being a layer-by-layer deposition process, necessarily imparts layered ordering throughout the depth of the polymer or copolymer that it produces. Thus, in various exemplary embodiments, the desired copolymer 113 can exhibit layered ordering throughout the depth of the desired copolymer 113. The oMLD process can also generate polymer products whose monomeric units are covalently connected into repeat units of three or more monomers. Hence, in various exemplary embodiments, the desired copolymer 113 can be so structured that each of the various monomer species that comprise the copolymer 113 are covalently connected into repeat units of three or more monomers. For example, a desired copolymer 113 can, in various embodiments, comprise the at least one first gas phase oxidant 111 (A) and the at least one second gas phase oxidant 111′ (B) covalently bonded in the pattern AAABBB ( . . . ), where “AAA” and “BBB” each represent repeat units of three of their respective monomer covalently bonded.

The at least one first gas phase oxidant 111 and/or at least one second gas phase oxidant 111′ can, without limitation and in various exemplary embodiments, include a quantity of one species of gas phase oxidant, a quantity of two species of gas phase oxidants present in a molar ratio relative to one another, or a quantity of more than two species of gas phase oxidants present in a molar ratio relative to one another.

For example, suitable candidates for the at least one first gas phase oxidant 111 and/or at least one second gas phase oxidant 111′ include, but are not limited to, halides and metal halides. In various exemplary embodiments, these can comprise Cl₂ gas, molybdenum pentachloride (MoCl₅), iron chloride (FeCl₃), tin chloride (SnCl₄), arsenic chloride (AsCl₅), rhenium chloride (ReCl₅), copper chloride (CuCl₂), palladium chloride (PdCl₂), antimony chloride (SbCl₅), vanadium chloride (VCl₄), niobium chloride (NbCl₅), tungsten chloride (WCl₅), and tantalum chloride (TaCl₅). In various exemplary embodiments, the at least one gas phase oxidant 111 and/or at least one second gas phase oxidant 111′ exhibit two-electron oxidation. In various exemplary embodiments, the at least one first gas phase oxidant 111 and/or at least one second gas phase oxidant 111′ exhibit three-electron oxidation, and are thereby capable of inducing exponential oMLD growth, wherein a single molecule of the at least one first gas phase oxidant and/or the a single molecule of the at least one second gas phase oxidant, once surface-bound, can oxidize multiple molecules of the at least one first gas phase monomer 110 and/or the at least one second gas phase monomer 110′.

Referring now to FIG. 1B, in various embodiments the oMLD process described above can be presented in further abstraction FIG. 1B to explain further variations of the enhanced oMLD polymer synthesis scheme of FIG. 1A that are within the scope of the present description. FIG. 1B presents the enhanced oMLD process as a cycle comprising at least two sub-cycles, a first sub-cycle A 115 and a second sub-cycle B 116. Sub-cycle A 115 comprises the steps depicted in boxes A-E of FIG. 1A, including a step of dosing the at least one gas phase monomer 110 (Box B of FIG. 1A), a subsequent purging step 114, a subsequent dosing of the at least one gas phase oxidant 111, and a subsequent purging step 114. In various exemplary embodiments, sub-cycle A 115 can be performed once before proceeding to sub-cycle B 116. In various exemplary embodiments, sub-cycle A 115 can be performed multiple times in sequence before proceeding to sub-cycle B 116. Sub-cycle B 116 comprises the steps depicted in boxes F-H of FIG. 1A, including a step of dosing the at least one second gas phase monomer 110′ (Box F of FIG. 1A), a subsequent purging step 114, a subsequent step of dosing the at least one second gas phase oxidant 111′, and a subsequent purging step 114. In various exemplary embodiments, sub-cycle B 116 can be performed once before proceeding to sub-cycle A 115. In various exemplary embodiments, sub-cycle B 116 can be performed multiple times in sequence before proceeding to sub-cycle A 115. In various exemplary embodiments, sub-cycle A can be performed with fewer repetitions than those of sub-cycle B, more repetitions than those of sub-cycle B, or a number of repetitions equal to those of sub-cycle B.

One of ordinary skill in the art can further envision cycles comprising more than two sub-cycles, with each sub-cycle comprising its own gas phase monomer and gas phase oxidant. These variations are considered to be within the scope of the present disclosure.

The preceding general description of the oMLD method has resulted in the demonstrated formation of various conformal thin film polymers, such as poly(3,4-ethylenedioxythiophene) (PEDOT). However, the results of applying this technique to synthesize other polymers have been mixed and have revealed surprising and powerful insights into the mechanisms by which oMLD polymerization occurs and how this polymerization may be tuned. The following description will first demonstrate a method of accommodating or otherwise incorporating gas phase monomers that resist oMLD growth with typical gas phase oxidants. Subsequently, the formation of anomalous functional groups during oMLD is described, as well as methods of tuning the formation of such groups.

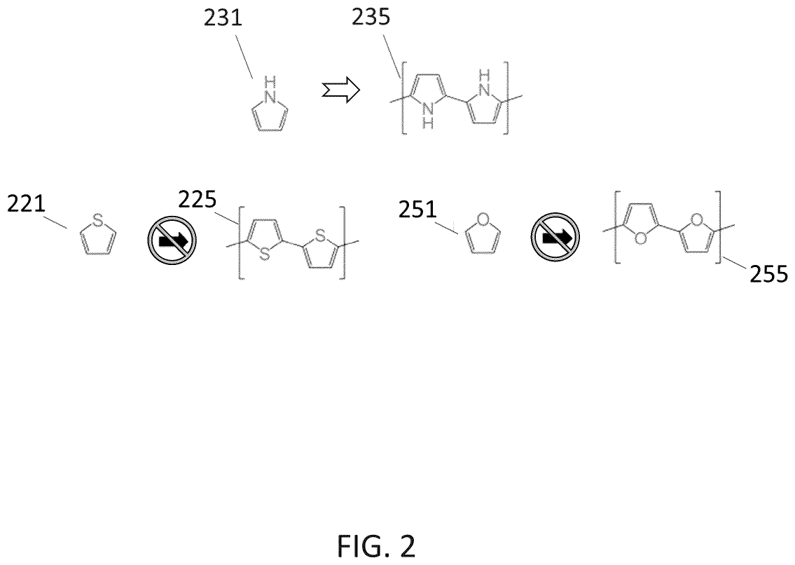

As mentioned, the enhanced oMLD methods described in FIGS. 1A and 1B enable the synthesis of copolymers from particular monomers that cannot be successfully integrated into polymers via the prior known oMLD methods. FIG. 2 provides several exemplary monomer species that either cannot successfully be integrated into a predicted polymer structure via prior oMLD methods or are inhibited in doing so.

As described below, there are further advantages of the enhanced oMLD methods of the present disclosure. Under known non-oMLD polymerization conditions such as solution polymerization, a thiophene (Thi) monomer species 221 is known to polymerize to form a polythiophene (pThi) structure 225, and a furan (Fu) monomer species 251 is known to polymerize to form a polyfuran (pFu) structure 255. Hence, it was predicted that prior oMLD polymerization methods, when applied to the Thi monomer species 221 and the Fu monomer species 251, would generate the pThi structure 225 and the pFu structure 255, respectively. Similarly, a pyrrole (Py) monomer species 231 can by polymerized by non-oMLD methods such as solution polymerization to form a polypyrrole structure 235. Hence, it was predicted that prior oMLD polymerization methods, when applied to the pyrrole monomer species 231, would result in the polypyrrole structure 235.

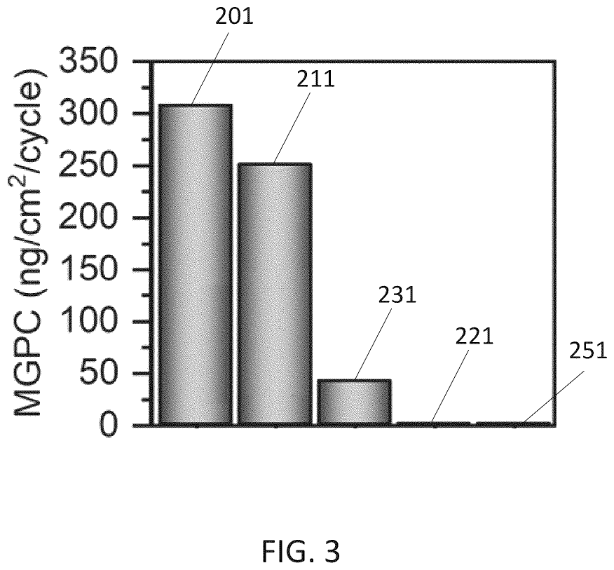

However, the polymerization of Py 231, Thi 221, and Fu 251 via prior oMLD methods was not uniformly successful, as shown in FIG. 3. FIG. 3 compares the mass gain per cycle for EDOT 201, PDA 211, Py 231, Thi 221, and Fu 251 using MoCl₅ as an oxidant. As is readily apparent to one skilled in the art, growth of EDOT 201 and PDA 211 to form PEDOT and pPDA, respectively, proceeds, generating impressive growth per oMLD cycle. However, under similar conditions, Py 231 growth proceeds markedly more sluggishly, and the growth of Thi 221 and Fu 251 appears to not proceed. As illustrated, the prior known oMLD approach for generating polymers is not uniformly successful and can vary depending on the chosen monomer. It has been surprisingly found that this challenge can be mitigated or even overcome, however, by careful consideration of copolymer agents and/or the characteristics of the oxidant, and by incorporation of the enhanced oMLD copolymer synthesis described above and with respect to FIGS. 1A-1B.

During the oMLD process of the present disclosure, layer-by-layer polymerization is held to proceed via a two-electron process in which a single oxidant molecule (e.g., first gas phase oxidant 111) oxidizes two monomer molecules (e.g., first and second gas monomers 110 and 110′). Therefore, the oxidant needs to be a sufficiently strong oxidizer to react with both monomer molecules. Proceeding from the presumption that oxidizing agents such as MoCl₅ are insufficiently strong oxidizers to polymerize either Thi 221 or Fu 251 monomer species alone, it was surprisingly found that Thi and Fu could nevertheless be incorporated into an oMLD-synthesized polymer by concomitantly providing another monomer species that is more readily oxidized.

For example, with reference to FIG. 1A, In various exemplary embodiments, oMLD processes of the present disclosure can incorporate monomers that are otherwise not amenable to oxidation by standard oxidizing agents by incorporating them into copolymers. In such exemplary embodiments, the at least one second gas phase monomer 110′ comprises a monomer species that is not readily oxidized by standard oMLD oxidants such as MoCl₅. Although the at least one second gas phase monomer 110′ cannot be oxidized by the at least one gas phase oxidant 111 on its own, the surface-bound adduct 112 is a stronger oxidant. By introducing the at least one second gas phase monomer 110′ after the formation of the surface-bound adduct 112, the at least one second gas phase monomer 110′ is capable of being oxidized to form the desired copolymer 113.

Accordingly, by selectively choosing monomer species the oMLD process of the present disclosure permits the incorporation of desirable chemical moieties into oMLD-synthesized polymers that would otherwise be too difficult to oxidize with the standard oxidants. In various exemplary embodiments, a monomer species that is too difficult to oxidize with standard oxidants is one whose oxidation potential is greater than 1.46 V vs. Standard Hydrogen Electrode (SHE). 1.46 V corresponds to the redox potential of the MoCl₄/MoCl₃ redox couple. See “Example 1” below for a detailed example of this process and proof of its successful incorporation of Thi 221 and Fu 251 monomer species into respective copolymer layers.

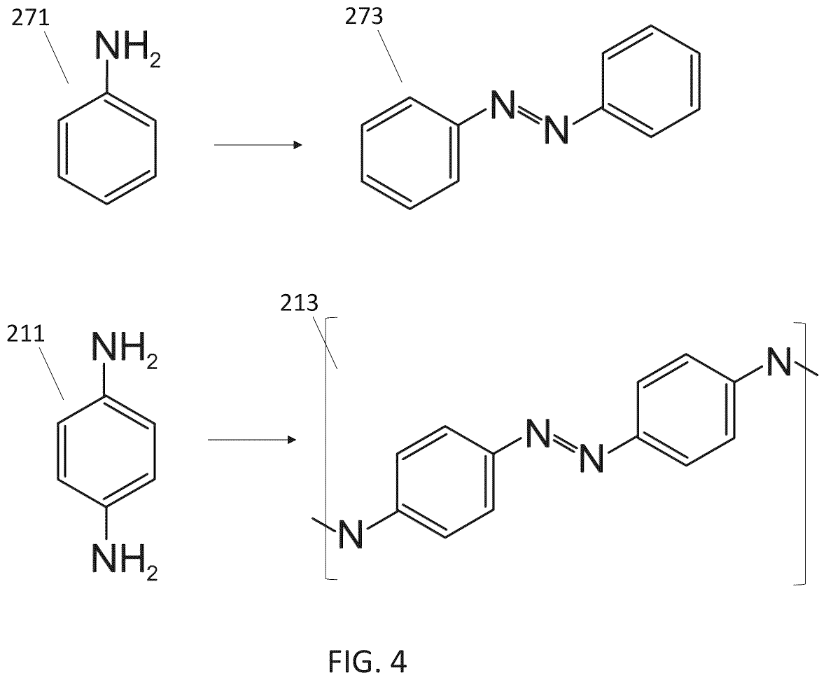

Some monomer species may struggle to form polymers from the oMLD process not because they are too difficult to oxidize, as just described and as exemplified in Example 1 below, but because the mechanisms of surface-direct oMLD polymerization result in such monomers bonding in undesirable or unexpected ways. For example, when applied to primary amine monomers, oMLD methods do not always successfully yield predicted polymer structures. Empirical testing yielded that the oMLD polymerization of monomers containing amines was surprisingly found to sometimes result in the generation of azo (R—N═N—R′) functional groups, although not all amines participated in the formation of the azo groups during oMLD polymerization. Azo groups are of particular interest for their redox chemistry and optomechanical properties. For example and as shown in FIG. 4, PDA 211, a monomer species with multiple primary amine functional groups, was found to sometimes form local azo structure 213 during oMLD. By contrast, aniline 271, a monomer species with a single primary amine functional group, was found to sometimes form small oligomers with azo groups 273, an irreversible redox reaction that does not engender long-range polymer formation.

Thus, an object of the present disclosure it to illustrate how azo functional groups can be integrated into the desired polymer 113 or the desired copolymer 113 via the oMLD method more reliably and avoid the irreversible formation of small oligomers. In various exemplary embodiments, a method for integrating azo functional groups into the desired copolymer 113 via oMLD process is a version of the oMLD synthesis method described earlier and with respect to FIGS. 1A and 1B. In order to synthesize the desired polymer or desired copolymer 113 such that it comprises azo functional groups, either the at least one gas phase monomer 110, the at least one second gas phase monomer 110′, or both must be a primary amine monomer. Unlike in the above description of a method of incorporating a high-oxidation-potential monomer into the desired polymer or desired copolymer 113, here, it is not necessary that the primary amine monomer be added only after a surface-bound adduct 112 is present. An exemplary polymer and an exemplary copolymer formed from at least one primary amine monomer are presented in Example 2 described below.

Furthermore, in various exemplary embodiments, the extent of azo group formation in a copolymer system produced via the oMLD processes disclosed herein. In various exemplary embodiments, a method for tuning the extent of azo group formation during an oMLD process for the formation of polymers is a variation of the enhanced oMLD copolymer synthesis method described earlier with respect to FIGS. 1A and 1B. In various exemplary embodiments, in order to synthesize a copolymer with a desired amount of incorporated azo groups, either the at least one gas phase monomer 110 or the at least one second gas phase monomer 110′ must be a primary amine monomer, and the other must not be a primary amine monomer. For example, if the at least one gas phase monomer 110 is chosen to be a primary amine monomer, then the at least one second gas phase monomer 110′ must not be a primary amine monomer.

Turning again to FIG. 1B, in various exemplary embodiments, the at least one second gas phase monomer 110′ can be chosen to be a primary amine monomer. In such a case, the subcycle-B 116 is one in which a primary amine monomer is incorporated into a surface adduct and/or polymerized. Polymerization of a primary amine monomer with other amine monomers via the oMLD processes disclosed herein can result in the formation of azo groups due to the direct covalent bonding of primary amines from two different primary amine monomers. Hence, by increasing the number of repetitions of subcycle-B 116, the likelihood of generating azo functional groups via direct covalent bonding of primary amines increases. By contrast, if one wishes to incorporate the primary amine monomer but avoid or tune down azo group formation, the number of repetitions of sub-cycle A 115 relative to the number of repetitions of sub-cycle B 116 can be increased, thereby increasing the formation of surface adducts and polymer layers that incorporate the at least one gas phase monomer 110, which, in such various examples, is chosen to not be a primary amine monomer. By increasing the relative ratio of the at least one gas phase monomer 110, which in these examples is not a primary amine monomer, one can effectively ‘surround’ the primary amine at least one second gas phase monomer 110′, thereby inhibiting the formation of amine-amine covalent bonds. Examples of copolymers with varying extents of azo group formation according to the described method are presented in Example 2 below.

The foregoing description of copolymers that, in various exemplary embodiments, include high-oxidation-potential monomers, primary amine monomers, and/or azo functional groups, as well as methods for producing and modifying the same, permit novel applications of oMLD polymerization processes of the present disclosure. Polymers of the present description can synthesized as polymer films, such as for electrodes, wherein such a film, in various exemplary embodiments, can be a conjugated heteroatomic polymer made layer-by-layer. In various exemplary embodiments, such a film can be any number of layers thick, including as few as one layer, wherein each layer has a thickness whose minimum is defined by the size of the at least one first gas phase monomer 110 or at least one second gas phase monomer 110′ of which each layer is comprised. In various exemplary embodiments, each layer may be made from more than two species of gas phase monomer, in which case the thickness of each layer is substantially defined by the thickness of the largest gas phase monomer which the layer comprises. In various exemplary embodiments, a polymer film has a thickness between 10 and 800 nm. In various exemplary embodiments, a gas phase monomer thickness is between 10 and 100 nm. In various exemplary embodiments, the conjugated heteroatomic polymer does not contain plasticizers, sidechains, or other free organic molecule additives.

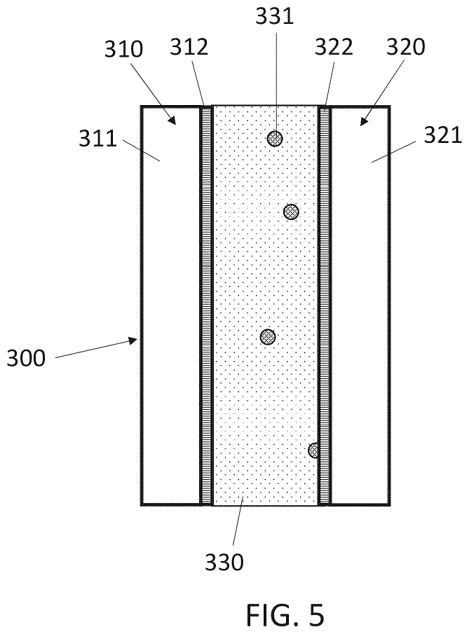

For example, the following describes an oMLD-derived polymer-based battery with energy densities that are at least competitive with modern lithium ion batteries and can feature electrodes that are not formed from metals. Turning to FIG. 5, in various exemplary embodiments, a battery 300, comprising an anode 310 and a cathode 321 on opposing ends of an electrolyte layer 330 is exemplarily illustrated. The anode 310 comprises a conductive anode support 311 on which is deposited a thin polymer coating 312, and the cathode comprises a conductive cathode support 321 on which is deposited a thin polymer coating 322.

In various exemplary embodiments, the thin polymer coating 312 is made from one or more monomers and is synthesized and deposited on the conductive anode support 311 according to the oMLD processes described herein. In various exemplary embodiments, the thin polymer coating 322 is made from one or more monomers and is synthesized and deposited on the conductive cathode support 321 according to the oMLD processes described herein.

In various exemplary embodiments, the thin polymer coating 312 comprises azo functional groups and in various exemplary embodiments, the thin polymer coating 312 comprises a copolymer synthesized in part from p-phenylenediamine 211, or derivatives or substituted versions thereof. In various exemplary embodiments, the thin polymer coating 312 is a polyazobenzene polymer.

Additionally, in various exemplary embodiments, the thin polymer coating 322 comprises oxygen atoms and in various exemplary embodiments, the thin polymer coating 322 comprises OH functional groups. Furthermore, in various exemplary embodiments, the thin polymer coating 322 is a copolymer synthesized in part from furan 251 or derivatives or substitute versions thereof and in various exemplary embodiments, the thin polymer coating 322 comprises a copolymer synthesized in part from quinone, hydroxyquinone, and/or furan 251 monomers, as well as any derivatives or substituted versions thereof.

Still further, in various exemplary embodiments and as depicted in FIG. 4, the electrolyte can comprise cation species 331, wherein exemplary cation species 331 include but are not limited to ionic species comprising lithium, sodium, potassium, and/or magnesium, or any other metal cation known to those of ordinary skill in the art. In various exemplary embodiments, the composition of the thin polymer coating 312 is such that it can undergo one or more redox reactions to bind with the cation species 331. For example, a polyazobenzene anode polymer comprising azo functional groups can undergo redox reactions to bind cation species 331 at or around −2V vs. the Standard Hydrogen Electrode (SHE). Additionally in various exemplary embodiments, the composition of the thin polymer coating 322 is such that it can undergo one or more redox reactions to bind with the cation species 331. For example, a copolymer of polyfuran and polyquinone can undergo on or more redox reactions to bind cation species 331 at or around +1V vs. SHE.

Furthermore, in various exemplary embodiments, the conductive anode support 311 comprises a conductive powder and/or a monolith support. In various exemplary embodiments, the conductive cathode support 321 comprises a conductive powder and/or a monolith support. Further yet, in various exemplary embodiments, the conductive anode support 311, the conductive cathode support 321, or both can by formed by oMLD processes, and in various exemplary embodiments, the electrolyte 330 can be any of the electrolyte formulations in use or theorized for use in batteries, without limitation and as known to one of ordinary skill in the art. In various exemplary embodiments, the electrolyte 330 can be a liquid, a solid-state electrolyte, a polymer, a foam, gel or other phase or morphology known to one of ordinary skill. In various exemplary embodiments, candidate formulations for the electrolyte 330 include but are not limited to 1:1 ethylene carbonate:dimethyl carbonate (EC:DMC) comprising LiPF₆, Li₇La₃O₁₂Zr₂ (LLZO), Li₁₀GeP₂S₁₂ (LGPS), polyethylene oxide, and polyacrylonitrile. In various exemplary embodiments, the electrolyte can comprise a polymer formed by the reaction of an alkali metal precursor and an organic polyol. In such exemplary embodiments, the alkali metal precursor is of the form MX, where M is an alkali metal and X is a ligand such as tert-butoxide, hexamethyldisilzane, 2,2,6,6,-tetramethyl-3,5-heptanedionato, cyclopentadienyl, or any other ligand known to one of ordinary skill in the art. In such exemplary embodiments, the organic polyol is an organic molecule that comprises more than two hydroxyl functional groups, examples of which include but are not limited to glycerol, xylitol, ptenaerythritol, and cyclitol.

The schematic of the battery 300 shown in FIG. 5 is merely exemplary, and in various alternative embodiments, the battery can take on arrangements other than that shown, such as nanolaminate and bipolar plate ‘stack’ configurations. In various exemplary embodiments, all or any one of the conductive anode support 311, thin polymer coating 312, conductive cathode support 321, thin polymer coating 322, and electrolyte 330 can be formed and deposited via oMLD. In various exemplary embodiments, such as certain battery stack configurations, the conductive anode support 311 and conductive cathode support 321 can be the same material and/or the same layer. As the following examples demonstrate, oMLD materials derived as described herein are of particular appeal for systems such as batteries because they can, in various exemplary forms, be exclusive of metals, be exclusive of sulfur heteroatoms, exhibit more controlled and/or facile synthesis and assembly, comprise functional groups that exhibit useful redox chemistry, and/or exhibit energy densities that match those of modern lithium ion batteries or even, in theory, exceed those of modern lithium ion batteries by up to 3 times. As Example 3 will make clear, polymers generated by the oMLD method described herein have properties that surpass those made by competing methods such as electrochemical deposition.

### SPECIFIC EXAMPLES

### Example 1: Incorporation of Furan and Thiophene Monomers into Copolymers

oMLD was performed in a two-stage series, alternating between 10 oMLD cycles comprising doses of pyridine followed by MoCl₅ oxidant (Py/MoCl₅) and 10 oMLD cycles using a high oxidation potential monomer (Thi or Fu) for a total of 400 oMLD cycles overall. These depositions can be described by a N[n(t_{A}:t_{Purge}:t_{B}:t_{Purge}):m(t_{C}:t_{Purge}:t_{B}:t_{Purge})] timing sequence where t_{A} is the Py does time, t_{B} is the MoCl₅ does time, t_{C} is the Fu does time (for pPy:Fu copolymer) or Thi dose time (for pPy:Thi copolymer), t_{Purge} is the purge time following each precursor dose, n is the number of A/B oMLD subcycles, m is the number of C/B oMLD subcycles, and N is the number of supercycles. For these depositions, N=20, n=10, m=10, t_{A}=10, t_{B}=60, t_{C}=10, and t_{Purge}=60. The pPy:Fu and pPy:Thi molecularly mixed copolymer films had spectroscopic ellipsometry (SE) measured thicknesses on Si of 15.4 and 17.7 nm, respectively. The resulting polymer films were analyzed by Raman spectroscopy, X-ray photoelectron spectroscopy (XPS), and cyclic voltammetry (CV).

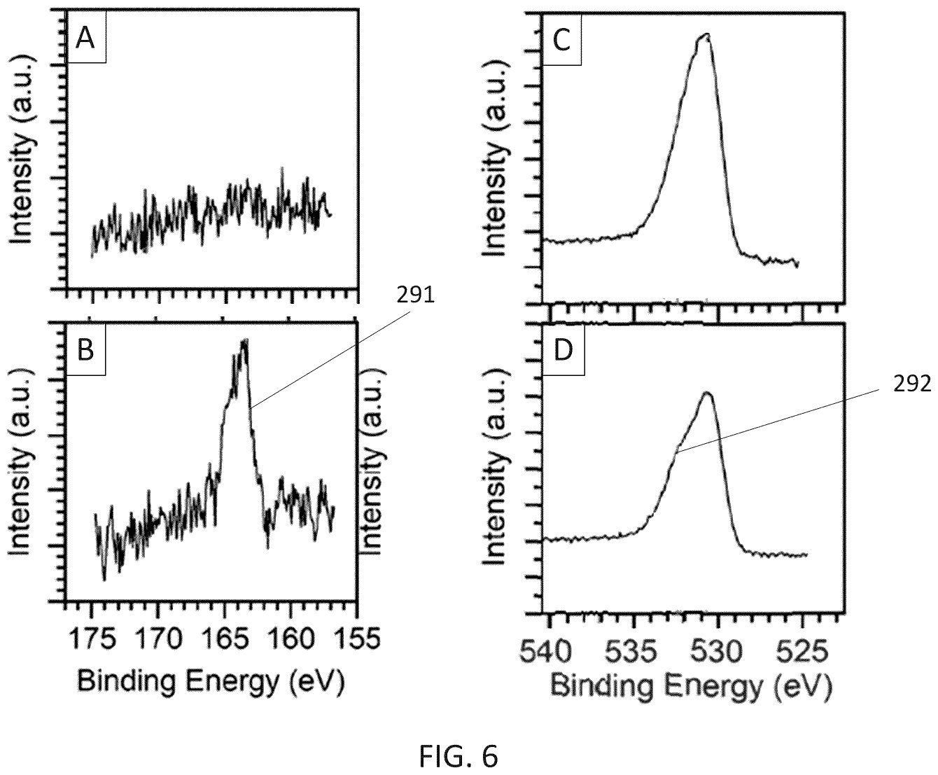

XPS results are highlighted in FIG. 6. Box A of FIG. 6 shows an XPS S 2p spectrum for a pPy polymer made according to the described oMLD method, while Box B of FIG. 6 shows an XPS S 2p spectrum for a pPy:Thi copolymer made according to the described oMLD method. The S 2p peak 291 present in the spectrum in Box B clearly indicates the successful incorporation of thiophene into the copolymer. Similarly, Box C shows an O 1s spectrum for pure pPy made according to the described oMLD method, while Box D shows an O 1s spectrum for a pPy:Fu copolymer made according to the described oMLD method. The presence of shoulder peak 292 indicates the successful incorporation of the oxygen-containing furan monomer into the copolymer product.

The addition of Fu monomers to pPy through controlled molecular assembly through oMLD increases the voltage window of electrochemical stability by 0.45 V and enhances the redox capacity from 267 mAh/g for pPy to 313 mAh/g for pPy:Fu. Likewise, the addition of Thi monomers to pPy through controlled molecular assembly through oMLD increases the voltage window for electrochemical stability by 0.15 V and enhances the redox capacity from 267 mAh/g to 369 mAh/g. By assembling Py and Thi monomers together by oMLD a 38% enhancement in electrochemical capacity vs oMLD pPy was achieved, as was a 90% of the maximum theoretical charge storage capacity of pPy of 411 mAh/g. This 369 mAh/g capacity exceeds the highest capacities reported for pPy to date and represents a higher capacity than cathode materials currently under consideration for next-generation lithium-ion batteries.

### Example 2: Identification of Azo Group Formation and Dynamics in Primary Amine Monomers

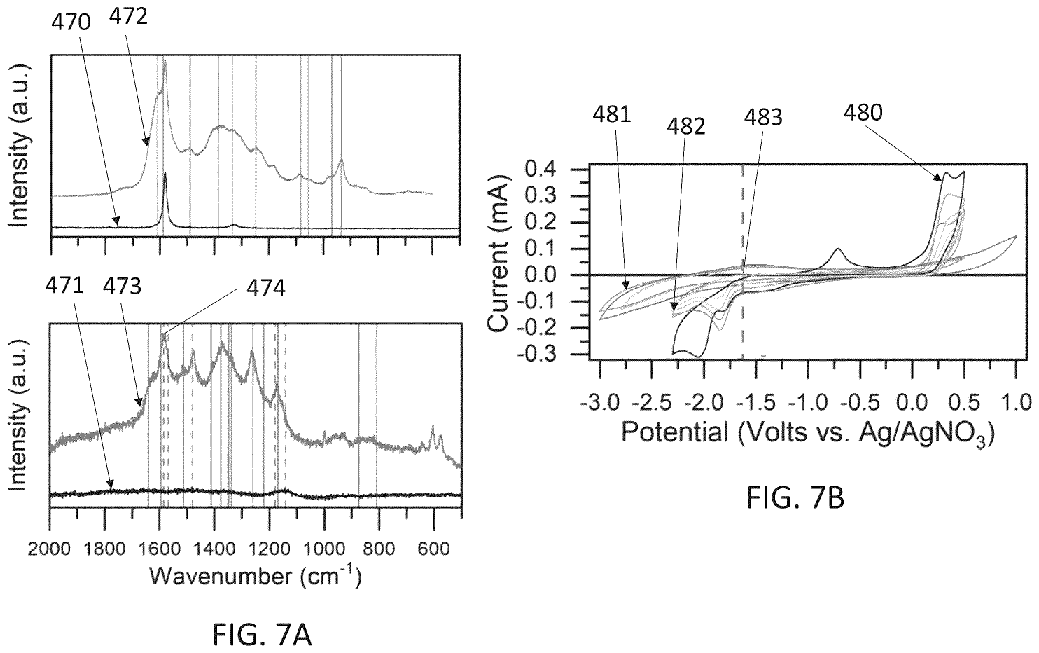

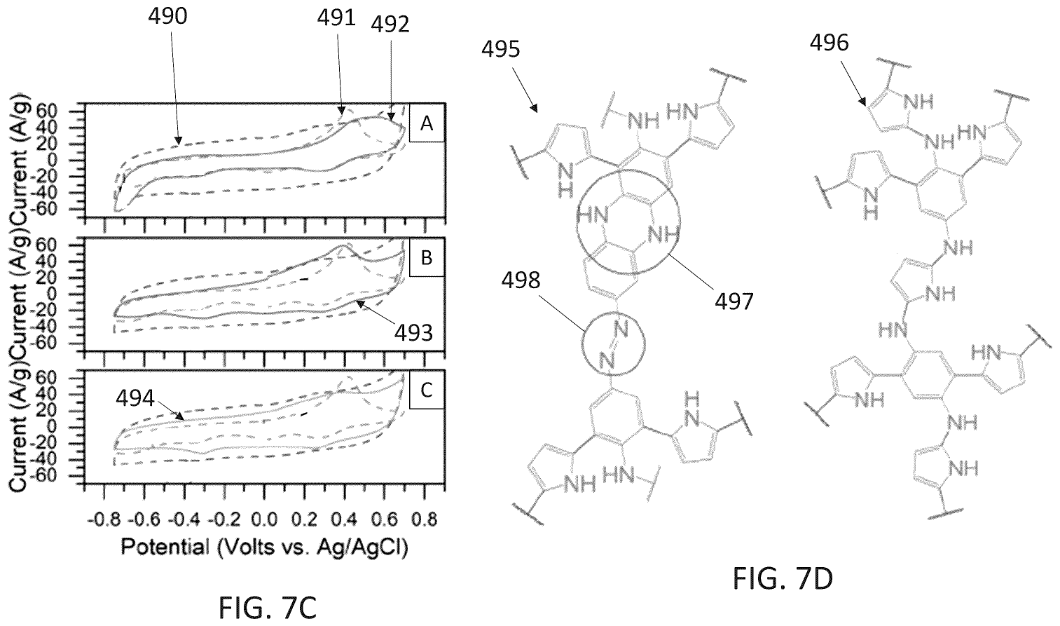

pPDA/MoCl₅, pPy/MoCl₅ and Ani/MoCl₅ omLD films were produced according to the methods disclosed herein. Raman spectroscopy was performed to analyze the pPy and pAni films for the presence of azo functional groups. FIG. 7A shows a Raman spectrum corresponding to bare pyrolytic graphite sheet (PGS) 470, a Raman spectrum corresponding to bare anodic aluminum oxide (AAO) 471, a Raman spectrum corresponding to pPy/MoCl₅ 472 formed via oMLD and deposited on bare PGS, and a Raman spectrum corresponding to pAni/MoCl₅ 473 formed via oMLD and deposited on bare AAO. The Raman spectrum corresponding to pAni/MoCl₅ 473 shows strong features at 1575 and 1580 cm⁻¹ that are consistent with the dominant peaks in azobenzene, confirming that pAni/MoCl₅ oMLD produces azobenzene. Note that these peaks are not present in the Raman spectrum corresponding to bare AAO 471, and thus are a product of the pAni/MoCl₅ polymer and not of the substrate. Relatedly, no such spectral features are present either in the Raman spectrum corresponding to bare PGS 470 nor in the Raman spectrum corresponding to pPy/MoCl₅ 472, indicating that the pyridine monomer does not by itself generate a polymer product comprising azo groups. Hence, pyridine, being a secondary amine monomer, does not engender azo group formation, while aniline, being a primary amine monomer, does engender azo group formation.

Further studies were conducted to investigate the dynamics of azo group formation during oMLD polymerization of primary amine monomers. FIG. 7B shows three superimposed CVs each taken at a sweep rate of 50 mV/s: a CV of bare PGS substrate 480, a CV of a 40.3 nm thick pPDA film 481, and a CV of a 121 nm thick pAni film 482. The pPDA and pAni films studied in this experiment were formed via oMLD with MoCl₅ oxidants and deposited on PGS substrates. Both the pPDA CV 481 and pAni CV 482 exhibit an electrochemical reduction feature 483 with an onset at approximately −1.74 V vs Ag/AgNO₃, consistent with the reduction of azo groups to form azo anion radicals. As multiple cycles of the pPDA CV 481 show, this redox process is reversible in pPDA films, with a capacity of 185 mAh/g measured on the oxidizing sweep. Initial cycling results up to 10 CV cycles suggest that the azo groups are stable in the condensed phase formed by PDA/MoCl₅ oMLD.

However, the feature 483 at −1.74 V vs Ag/AgNO₃ is indicative of an irreversible electrochemical redox process, and thus decreases in magnitude with repeated cycling. This decrease is attributable to the dissolution of azobenzene molecules upon electrochemical reduction to form azobenzene anion radicals. Because each Ani monomer has only one amine group, the reaction of two Ani molecules is expected to form azobenzene or short-chain azo oligomers that easily dissolve in the nonaqueous electrolyte when charged. This has been further confirmed with UV-Vis spectroscopy of the electrolyte after CV cycling of the Ani/MoCl₅ oMLD films in acetonitrile, which showed an absorption peak at 300-350 nm, consistent with the presence of azobenzene. Also observed was a visible loss of the deposited Ani/MoCl₅ layer from PGS following electrochemical cycling for the area of PGS sample exposed to the electrolyte.

### Example 3: Controlling Polymer Structure from oMLD of Molecularly Assembled Py/PDA Copolymers

Films were grown via oMLD of pPy, pPDA, and copolymers of Py and PDA according to the methods described herein. FIG. 7A boxes A-C show multiple CVs with features representative of the electrochemical redox profile of these films. FIG. 7A boxes A-C all show superimposed CVs of pPy 490 and of pPDA 491. Additionally, FIG. 7A box A shows a superimposed CV of a copolymer generated with a cycle ratio of 1:1 Py:PDA 492, FIG. 7A box B shows a superimposed CV of a copolymer generated with a cycle ratio 5:1 Py:PDA 493, and FIG. 7A box C shows a superimposed CV of a copolymer generated with a cycle ratio 20:1 Py:PDA 494. If the monomers Py and PDA, upon copolymerization via oMLD, were to form discrete pPDA and pPy domains, one would expect that the redox activity for these copolymers would appear as a superposition of the electrochemical responses seen in the pPy CV 490 and the pPDA CV 491. Instead, one observes a response where the qualitative shape of the CV changes depending on the Py/PDA cycle ratio. This indicates that by alternating doses of the Py and PDA monomers during oMLD growth in different ratios, one controls the assembly of these monomers to form qualitatively different local molecular structures with different electrochemical properties. For the 1:1 Py/PDA cycle ratio, one observes a CV 492 that is similar to PDA-only oMLD films but with enhanced redox activity on the oxidizing sweep at +0.6 V and on the reducing sweep at −0.7 V vs Ag/AgCl relative to PDA only oMLD. Although the redox potential of each monomer may be expected to shift based on the blending of molecular orbitals from these monomers within the copolymer structure, it appears that at this 1:1 cycle ratio, the redox potentials of pPDA are unshifted, and the electrochemical activity from pPy is only observed after fully oxidizing or reducing the pPDA component of the film. One notes that this hysteresis effect for charge transfer observed for the CV of the 1:1 cycle ratio of Py/PDA 491 in may be of interest for neuromorphic computing elements and other electronics applications (e.g., diodes).

This hysteresis effect is attributable to branching effects from assembling the two monomers into a copolymer. For this 1:1 cycle ratio, the fraction of pPy in the film is expected to be small—the growth rate of pPy oMLD at 150° C. is only 0.09 nm/cycle, corresponding to −0.23 monolayers of pPy, whereas the growth rate of pPDA oMLD at 150° C. is 1.35 nm/cycle, corresponding to −2.4 monolayers of pPDA. Based on the relative growth rates for the two monomers, one expects that the polymer films for the 1:1 cycle ratio contain ˜90% PDA monomers and −10% Py monomers. At this low molar ratio of Py, one expects that Py monomers react on PDA in the most favorable ortho position, such that electrons initially flow in/out of the connected pPDA network and only transfer to branching Py monomers after oxidizing/reducing the PDA molecular constituents, giving rise to the irreversible electrochemical behavior observed for the 1:1 Py/PDA cycle ratio.

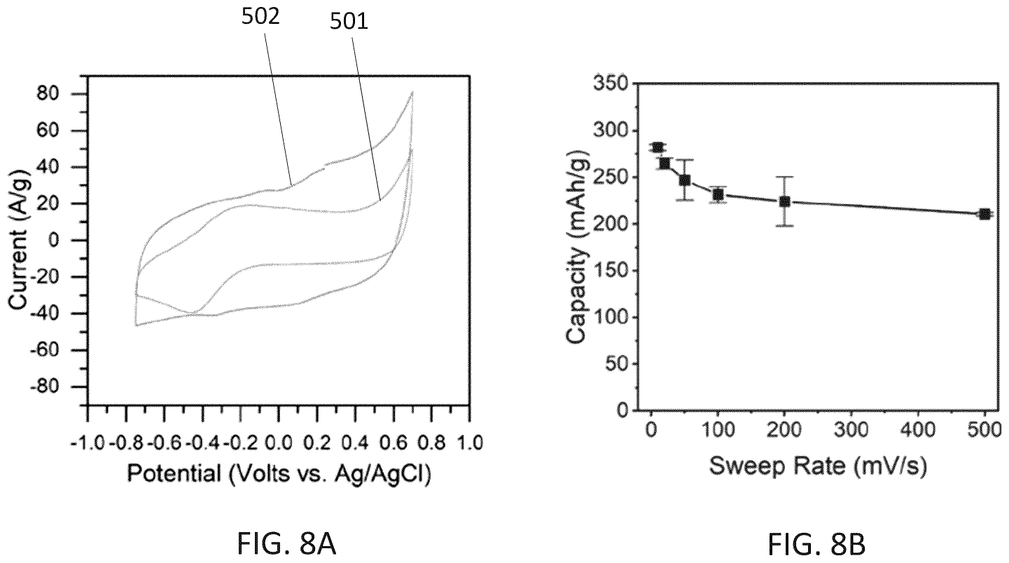

To confirm this interpretation, the cycle ratio of Py/PDA from 1:1 was increased to 5:1 and 20:1. The film thicknesses for the data reported in FIG. 8A were 20.4, 40.3, 48.5, 49.7, and 29.5 nm for Py, PDA, and 1:1, 5:1, 20:1 Py/PDA copolymer films, after 150, 30, 30, 150, and 210 total oMLD cycles (sum of Py/MoCl₅ and PDA/MoCl5 cycles), respectively. Based on the growth rates of the independent Py/MoCl₅ and PDA/MoCl₅ oMLD chemistries, the 5:1 and 20:1 cycle ratios correspond to −1:2 and −2:1 molar ratios of Py/PDA monomers, respectively, within the molecularly assembled copolymer films. In FIG. 8A, one sees that as the ratio of Py/PDA oMLD cycles increases above 1:1 to 5:1 and 20:1, the redox process arising from the pPy constituent of the film (E₀=−0.2 V vs Ag/AgCl) becomes more reversible. On the oxidizing sweep, the additional charge storage capacity provided from introducing Py into pPDA shifts from a redox potential of 0.6 V at a 1:1 cycle ratio (higher potential than the oxidation peak for pPDA) to a potential of 0.2 V for the 5:1 and 20:1 cycle ratio (lower potential than the oxidation peak for pPDA). Likewise, on the reducing sweep, as the amount of Py within the film increases, the amount of cathodic current at a potential of −0.7 V decreases, and the amount of anodic current between +0.3 and −0.5 increases. Under the 20:1 cycle ratio condition, one expects that Py monomers more completely surround PDA monomers within the copolymer film, as depicted in FIG. 8C. The 5:1 and 20:1 cycle ratios (with ˜1:2 and ˜2:1 molar ratios of each monomer based on the QCM growth rates of each isolated monomer) exhibit qualitatively different redox features from either the PDA-only or Py-only polymers, indicating that molecular assembly of these monomers into intimate copolymers causes different reactions and/or molecular orbital mixing for adjacent monomers, impacting the equilibrium redox potentials one observes. By adjusting the cycle ratio of the two monomers, one achieves different molecular structure and monomer interaction effects, yielding different redox properties for each copolymer composition.

Comparative depictions of the structure of a copolymer 495 formed from a 1:1 cycle ratio of Py:PDA and the structure of a copolymer 496 formed from a 20:1 cycle ratio of Py:PDA are shown in FIGS. 8B-8C. Note that a relative increase in the Py monomer cycle relative to PDA results in a decrease in the presence of the phenazine moiety 497 as well as the azo moiety 498. Hence, by tuning the cycle ratio of these two monomers, one of which is a primary amine, one can effectively tune the relative population of azo and other functional groups in the final copolymer product.

### Example 4: Comparison of oMLD pPy Film and Electrodeposited pPy

FIG. 8A shows a comparison of the CV characteristics of pPy generated by oMLD vs. pPy generated by electrochemical deposition. The electrochemically deposited pPy was grown to a thickness of 30.4 nm (as measured by SE) on a gold electrochemical quartz crystal microbalance (EQCM) electrode using known pulsed electrodeposition procedures (see Gettler, R.; Young, M. J. Multimodal Cell with Simultaneous Electrochemical Quartz Crystal Microbalance and in Operando Spectroscopic Ellipsometry to Understand Thin Film Electrochemistry. Rev. Sci. Instrum. 2021, 92, No. 053902. and Wyatt, Q. K.; Young, M. J. Pulsed Electrodeposition of Ultrathin Polyaniline Films and Mechanistic Understanding of Their Anion-Mediated Electrochemical Behavior. J. Electrochem. Soc. 2020, 167, No. 110548.). The mass of the final pPy film measured via EQCM was 5.56 μg, corresponding to a density of 1.34 g/cm³. The electrodeposited pPy film exhibited a specific capacity of 128.4 mAh/g at a sweep rate of 50 mV/s, consistent with typical capacities of ˜140 mAh/g reported for pPy. The 20.4 nm thick oMLD pPy film was deposited using 150 oMLD cycles at a growth temperature of 150 degrees Celsius. The pPy thickness was measured via SE on Si wafers placed adjacent to each PGS sample in the reactor chamber. Multiplying the thickness by the electrode area (1.21 cm²) and assuming a density of 1.5 g/cm³ for pPy, the specific capacity was calculated to be 258 mAh/g for the oMLD pPy film.

The CV 502 of the oMLD pPY film shown in FIG. 8A shows a visibly higher current (in A/g) than the electrodeposited pPy, consistent with this higher capacity. Also of note is that the CV 502 of the oMLD pPy is qualitatively different from the CV 501 for the electrodeposited pPy and exhibits an additional redox peak at more oxidizing potential (+0.2 V vs Ag/AgCl). This peak is attributable to the formation of different local structures within the oMLD pPy film, providing an enhanced electrochemical capacity. Specifically, it is held that the MoClₓ residue within the pPy film resulting from the oMLD process helps to prevent pore collapse of the pPy polymer fibers and provide a higher electrochemical capacity.

Capacity vs. sweep rate data is presented in FIG. 8B, derived from CVs of a 5.5 nm pPy film deposited via oMLD on PGS, with data from sweep rates of 100, 200, and 300 mV/s shown. The third CV measured at each sweep rate was used to establish the capacity vs. sweep rate data in FIG. 8B. Using these thickness values and assuming a density of 1.5 g/cm 3 for the pPy, one calculates a charge capacity of 282 mAh/g (68% of pPy's theoretical capacity) at a sweep rate of 10 mV/s (˜145 s charge time) and a capacity of 211 mAh/g (50% of pPy's theoretical capacity) at a charge rate of 500 mV/s (2.9 s charge time). Furthermore, increasing the charge rate by 50× from 10 to 500 mV/s only led to a 25% reduction in charge capacity. A log-log analysis of current vs sweep rate for the data in FIG. 9B (not shown) identifies that the charge storage for these 5.5 nm pPy films is composed of 15% diffusive and 85% capacitive behavior—indicating rapid charging of these thin redox-active layers. The double layer capacity of bare PGS substrates corresponded to only 10% of the total capacity at 10 mV/s sweep rate and 5% of the total capacity at a 500 mV/s sweep rate—a small fraction of the capacitive charge storage from the log-log analysis.

Based on the above analysis, the electrochemical capacities for thin-film oMLD pPy are initially as high as 282 mAh/g. This is ˜2 times higher than typical values of the electrochemical capacity reported for pPy formed by other synthesis methods. For reference, assuming every nitrogen atom yields one stoichiometric electron transfer, the maximum theoretical specific capacity for pPy is 412 mAh/g. However, typical values of charge storage capacity for pPy are ˜140 mAh/g, corresponding to ˜⅓ of the theoretical capacity. The highest capacity value reported for electrodeposited pPy is 133 mAh/g (480 F/g over 1.0 V potential window) at a sweep rate of 10 mV/s, and the highest value from the chemical oxidative formation of pPy is 111 mAh/g (500 F/g over a 0.8 V potential window) at a sweep rate of 2 mV/s. These values are consistent with the capacity of 128.4 mAh/g measured on a 30.5 nm thick electrodeposited pPy as seen in FIG. 8A.

The practical capacity limit for pPY of 140 mAh/g has been thought to originate from the irreversible formation of electrically resistive and nonideal polymer structures arising from uncontrolled polymer formation, limiting the activity to ˜⅓ of amine groups within pPy. The 2-fold enhancement in the electrochemical capacity observed with oMLD methods is attributed here to three factors: (1) controlled oMLD surface reactions generating favorable local polymer structures for redox reactivity, (2) incorporation of MoClₓ into the polymer structure to prevent pore collapse of the pPy, and (3) reduction in the length scale for ion and electron transport enabled by thin film growth. Previous vapor phase polymerization (VPP) deposition studies have only achieved capacities of 118 mAh/g for pPy by oxidative chemical vapor deposition (oCPD) and 29 mAh/g for pAni by oCVD. However, oCVD proceeds via homogenous reactions like electrodeposition and chemical oxidation and is therefore expected to produce similar molecular structures (and electrochemical capacities) to pPy formed by electrodeposition and/or chemical oxidation.

In view of the above, it will be seen that the several objects and advantages of the present invention have been achieved and other advantageous results have been obtained. The polymer and copolymers described herein, as well as their methods of production and control and the applications for them, constitute a significant advance in the ability to synthesize and use metal-free, high-capacity polymer materials.

As various changes could be made in the above constructions without departing from the scope of the invention, it is intended that all matter contained in the above description or shown in the accompanying drawings shall be interpreted as illustrative and not in a limiting sense.

What is claimed is:

1. A method of generating a copolymer via oMLD, said method comprising the steps of:
a. performing at least one first oMLD subcycle, comprising the steps of:
i. introducing a fixed quantity of at least one first monomer species to an oMLD reaction chamber; and,
ii. subsequently introducing a fixed quantity of a first metal halide oxidant to the oMLD reaction chamber;
b. performing at least one second oMLD subcycle, comprising the steps of:
i. introducing a fixed quantity of at least one second monomer species to the oMLD reaction chamber; and,
ii. subsequently introducing a fixed quantity of a second metal halide oxidant to the oMLD reaction chamber; and,
c. optionally repeating the at least one first oMLD subcycle and the at least one second oMLD subcycle in alternation until the copolymer has a desired thickness;
wherein the first monomer species and the second monomer species can be the same or different monomer species, and further wherein the first metal halide oxidant and the second metal halide oxidant can be the same or different metal halide oxidants.

2. The method of claim 1 wherein the second monomer species has an oxidation potential such that the second monomer species cannot be oxidized by the first metal halide or the second metal halide.

3. The method of claim 1 wherein the second monomer species is thiophene.

4. The method of claim 1 wherein the second monomer species is furan.

5. The method of claim 1 wherein either the first monomer species or the second monomer species comprises at least two primary amine functional groups.

6. The method of claim 1 wherein either the first monomer species or the second monomer species is para-phenylenediamine.

7. The method of claim 5 wherein an extent of azo group formation in the copolymer can be increased by increasing a number of repetitions of the first subcycle relative to the second subcycle, if the first monomer species comprises the at least one primary amine functional group, or by increasing a number of repetitions of the second subcycle relative to the first subcycle, if the second monomer species comprises the at least one primary amine functional group.

8. An electrically conductive conjugated heteroatomic polymer that has a charge capacity that is at least 50% of a theoretical charge capacity for said electrically conductive conjugated heteroatomic copolymer.

9. The polymer of claim 8 wherein it is made from an oMLD process.

10. The polymer of claim 8 wherein it is exclusive of plasticizers, sidechains, or other free organic molecule additives.

11. The polymer of claim 8 further comprising azo functional groups.

12. The polymer of claim 8 further comprising the polymerized form of one or more high oxidation potential monomeric species, such that the high oxidation potential monomeric species have oxidation potentials higher than 1.46 V versus SHE.

13. The polymer of claim 8 further wherein it has a charge capacity that is at least 68% of a theoretical charge capacity for said electrically conductive copolymer.

14. The polymer of claim 8 wherein the monomers that comprise the polymer exhibit layered ordering throughout the depth of the polymer.

15. The polymer of claim 8 wherein it comprises one or more monomeric species, further wherein monomers of each monomeric species are covalently connected into repeat units of three or more monomers.

16. A polymer film comprising a conjugated heteroatomic polymer and comprising one or more layers, wherein each layer comprises one or more monomer species, and wherein each layer has a thickness defined by the one or more monomer species.

17. The polymer film of claim 16, wherein the polymer film thickness is between 10 and 800 nm.

18. The polymer film of claim 17, wherein the polymer film thickness is between 10 and 100 nm.

19. The polymer film of claim 16, wherein the conjugated heteroatomic polymer does not contain plasticizers, sidechains, or other free organic molecule additives.

20. The polymer film of claim 16, wherein it is made from an oMLD process.
